(19) United States
(12) Patent Application Publication
(10) Pub. No.: US 2024/0337924 A1
(43) Pub. Date: Oct. 10, 2024

(54) PHOTOSENSITIVE RESIN COMPOSITION, PHOTOSENSITIVE RESIN LAYER USING THE SAME AND COLOR FILTER

(71) Applicant: SAMSUNG SDI CO., LTD., Yongin-si (KR)

(72) Inventors: Junghwa LEE, Suwon-si (KR); Jhuo JUNG, Suwon-si (KR); Chang-Hyun KWON, Suwon-si (KR); Gwangil JEON, Suwon-si (KR); Heejo MOON, Suwon-si (KR); Baek Soung PARK, Suwon-si (KR)

(21) Appl. No.: 18/507,311

(22) Filed: Nov. 13, 2023

(30) Foreign Application Priority Data
Apr. 6, 2023 (KR) 10-2023-0045634

(51) Int. Cl. G03F 7/00; G03F 7/038

(52) U.S. Cl. CPC G03F 7/0007; G03F 7/038; G02B 5/223

(57) ABSTRACT

A photosensitive resin composition, a photosensitive resin layer, and a color filter manufactured using the same. The photosensitive resin composition including a colorant; a photopolymerizable compound; a photopolymerization initiator, a binder resin; and a solvent; wherein the colorant includes a pigment and additive represented by Chemical Formula 1:

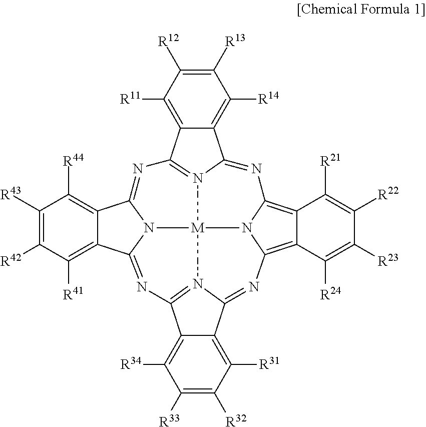

### CROSS-REFERENCE TO RELATED APPLICATION

This application claims priority to and the benefit of Korean Patent Application No. 10-2023-0045634, filed in the Korean Intellectual Property Office on Apr. 6, 2023, the entire contents of which are incorporated herein by reference.

### BACKGROUND

### 1. Field

Embodiments relate to a photosensitive resin composition, a photosensitive resin layer using the same, and a color filter.

### 2. Description of the Related Art

Recently, the demand for solid image sensors is increasing in order to widely spread technologies such as autonomous vehicles, factory automation, and the like as well as mobile cameras.

### SUMMARY

The embodiments may be realized by providing a photosensitive resin composition including a colorant; a photopolymerizable compound; a photopolymerization initiator; a binder resin; and a solvent, wherein the colorant includes a pigment and an additive represented by Chemical Formula 1:

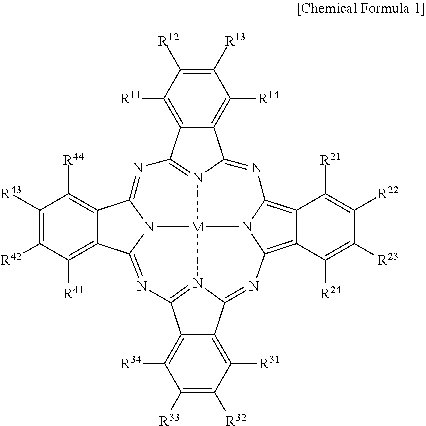

in Chemical Formula 1, M is Zn or Cu; R¹¹ to R¹⁴, R²¹ to R²⁴, and R³¹ to R³⁴ are each independently a hydrogen atom, a halogen atom, a hydroxy group, or a substituted or unsubstituted C1 to C20 alkyl group; R⁴¹ to R⁴⁴ are each independently a halogen atom, or a substituent represented by *-L¹-L²-A, provided that at least one of R⁴¹ to R⁴⁴ is a substituent represented by *-L¹-L²-A; L¹ is *—O—* or *—S—*; L² is a single bond or a substituted or unsubstituted C6 to C20 arylene group; and A is a carboxyl group or a meth (acrylate) group.

The embodiments may be realized by providing a photosensitive resin layer manufactured using the photosensitive resin composition according to an embodiment.

The embodiments may be realized by providing a color filter including the photosensitive resin layer according to an embodiment.

The embodiments may be realized by providing a CMOS image sensor including the color filter according to an embodiment.

### BRIEF DESCRIPTION OF THE DRAWINGS

Features will be apparent to those of skill in the art by describing in detail exemplary embodiments with reference to the attached drawings:

FIGS. 1 to 3 show 2.8 um pattern CDs of Example 1 and Comparative Examples 1 and 3, respectively.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

As used herein, when specific definition is not otherwise provided, “substituted” refers to replacement of at least one hydrogen atom of a compound by a substituent of a halogen atom (F, Cl, Br, or I), a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C30 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, or a combination thereof.

As used herein, when specific definition is not otherwise provided, a “heterocycloalkyl group”, a “heterocycloalkenyl group”, a “heterocycloalkynyl group,” and a “heterocycloalkylene group” refer to each cyclic compound of cycloalkyl, cycloalkenyl, cycloalkynyl, and cycloalkylene including at least one heteroatom of N, O, S, or P.

As used herein, when specific definition is not otherwise provided, “(meth)acrylate” refers to both “acrylate” and “methacrylate”.

As used herein, when a definition is not otherwise provided, the term “combination” refers to mixing or copolymerization. Additionally, “copolymerization” refers to block copolymerization to random copolymerization, and “copolymer” refers to block copolymerization to random copolymerization.

As used herein, when a definition is not otherwise provided, hydrogen is bonded at the position when a chemical bond is not drawn where supposed to be given.

As used herein, when specific definition is not otherwise provided, “*” refers to a linking point with the same or different atom or chemical formula.

As used herein, when a definition is not otherwise provided, “particle diameter” may mean a diameter of a particle, and the diameter of the particle may be a Z-average value of the particle diameter measured through dynamic light scattering.

As used herein, the term “or” is not an exclusive term, e.g., “A or B” would include A, B, or A and B.”

### (Photosensitive Resin Composition)

Some example embodiments may provide a photosensitive resin composition including, e.g., (A) a colorant; (B) a photopolymerizable compound; (C) a photopolymerization initiator; (D) a binder resin; and (E) a solvent. In an implementation, the colorant may include a pigment and an additive represented by Chemical Formula 1.

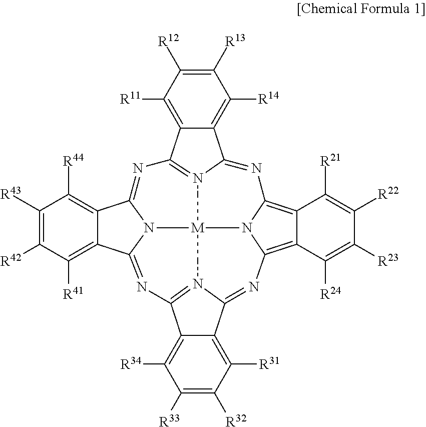

In Chemical Formula 1, M may be, e.g., Zn or Cu; R¹¹ to R¹⁴, R²¹ to R²⁴, and R³¹ to R³⁴ may each independently be or include, e.g., a hydrogen atom, a halogen atom, a hydroxy group, or a substituted or unsubstituted C1 to C20 alkyl group; R⁴¹ to R⁴⁴ may each independently be or include, e.g., a halogen atom, or a substituent represented by *-L¹-L²-A, provided that at least one of R⁴¹ to R⁴⁴ is a substituent represented by *-L¹-L²-A; L¹ may be or include, e.g., *—O—* or *—S—*; L² may be or include, e.g., a single bond or a substituted or unsubstituted C6 to C20 arylene group; and A may be, e.g., a carboxyl group or a meth (acrylate) group.

### (A) Colorant

The colorant may include a pigment and an additive, and may further include a dispersion resin, a dispersant, a dispersion solvent, or a combination thereof.

When a color filter is formed by using a photosensitive resin composition including the pigment, there may be limitations in luminance and a contrast ratio due to a particle size of the pigment. In order to overcome these limitations, a material may be needed that helps dispersion of the pigment, while suppressing re-agglomeration.

In order to make the color filter-particularly, a negative-type color filter-small and thin, PWC (pigment weight concentration) can be increased, which may deteriorate regularity and linearity of a pattern of the color filter. In order to solve this problem, a material with excellent coloring powder, contrast ratio, patternability, or the like may be required.

Some example embodiments, in order to comprehensively solve the above problems, use an additive having excellent coloring power, contrast ratio, patternability, and the like as well as high dispersibility and dispersion stability. The additive may not only function as ‘a dispersant’ suppressing reagglomeration as well as helping dispersion of the pigment but may also function as a ‘colorant’ achieving excellent coloring power, contrast ratio, patternability, and the like.

In an implementation, the additive of some example embodiments may be a compound represented by Chemical Formula 1 having a structure that a substituent such as a carboxyl group, a (meth)acrylate group, or the like may be asymmetrically substituted in a phthalocyanine parent moiety.

The substituent such as the carboxyl group, the (meth)acrylate group, or the like may covalently bond with the dispersant or the dispersion resin, and the phthalocyanine parent moiety may covalently bond with the pigment. Through this interaction (dispersant and/or dispersion resin↔additive↔pigment), the additive of some example embodiments may help suppress the reagglomeration as well as help the dispersion of the pigment.

In an implementation, the phthalocyanine parent moiety itself may be a blue auxochromophore (dye) and may exhibit excellent blue coloring power, contrast ratio, patternability, and the like.

The additive of some example embodiments may function as the ‘dispersant and the ‘colorant.’

In an implementation, the photosensitive resin composition according to some example embodiments may realize a color filter and CIS exhibiting excellent coloring power, contrast ratio, patternability, and the like as well as having high dispersibility and dispersion stability.

Hereinafter, the elements that constitute the colorant, such as the pigment, additives, dispersion resin, dispersion solvent, and dispersant, will be described in more detail.

First, the additive is described as follows.

M may be, e.g., Zn or Cu.

R¹¹ to R¹⁴, R²¹ to R²⁴, and R³¹ to R³⁴ may each independently be or include, e.g., a hydrogen atom, a halogen atom, a hydroxy group, or a substituted or unsubstituted C1 to C20 alkyl group.

In an implementation, R¹¹ to R¹⁴ may be all hydrogen atoms or all halogen atoms. Herein, the halogen atom may be a chlorine atom.

In an implementation, one of R²¹ to R²⁴ may be a substituted or unsubstituted C1 to C20 alkyl group, and the rest may be all hydrogen atoms. In contrast to the case where R²¹ to R²⁴ are all hydrogen atoms, if one of R²¹ to R²⁴ is a substituted or unsubstituted C1 to C20 alkyl group, solubility of the additive represented by Chemical Formula 1 in the solvent may be improved. In an implementation, one of R²¹ to R²⁴ may be a branched C4 alkyl group (tert-butyl group), and the rest may be all hydrogen atoms.

In an implementation, R³¹ to R³⁴ may be all hydrogen atoms.

In an implementation, any one of R⁴¹ to R⁴⁴ may be a substituent represented by *-L¹-L²-A; and the rest may be all hydrogen atoms or all halogen atoms. Herein, L¹ may be *—O—*, L² may be a phenylene group, and A may be a carboxyl group or a meth (acrylate) group.

In an implementation, the substituent represented by *-L¹-L²-A may be represented by Chemical Formula 2:

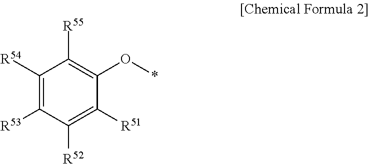

In Chemical Formula 2, R⁵¹ to R⁵⁵ may each independently be or include, e.g., a hydrogen atom, a carboxyl group, or a meth (acrylate) group, provided that at least one of R⁵¹ to R⁵⁵ is a carboxyl group, or a meth (acrylate) group.

In an implementation, the additive represented by Chemical Formula 1 may be a compound represented by Chemical Formula 1-1.

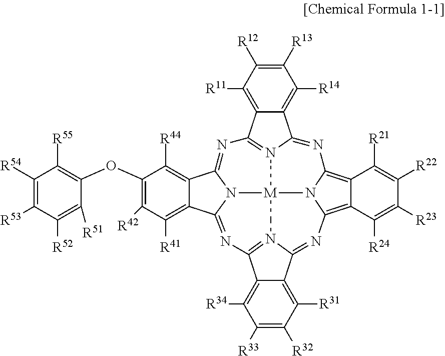

In Chemical Formula 1-1, M may be, e.g., Zn or Cu; R¹¹ to R¹⁴, R²¹ to R²⁴, and R³¹ to R³⁴ may each independently be or include, e.g., a hydrogen atom, a halogen atom, a hydroxy group, or a substituted or unsubstituted C1 to C20 alkyl group; R⁴¹, R⁴², and R⁴⁴ may each independently be or include, e.g., a hydrogen atom or a halogen atom; and R⁵¹ to R⁵⁵ may each independently be or include, e.g., a hydrogen atom, a carboxyl group, or a meth (acrylate) group, provided that at least one of R⁵¹ to R⁵⁵ is a carboxyl group or a meth (acrylate) group.

The description of each substituent may be as described above.

In an implementation, the additive represented by Chemical Formula 1 may be represented by one of the following chemical formulae:

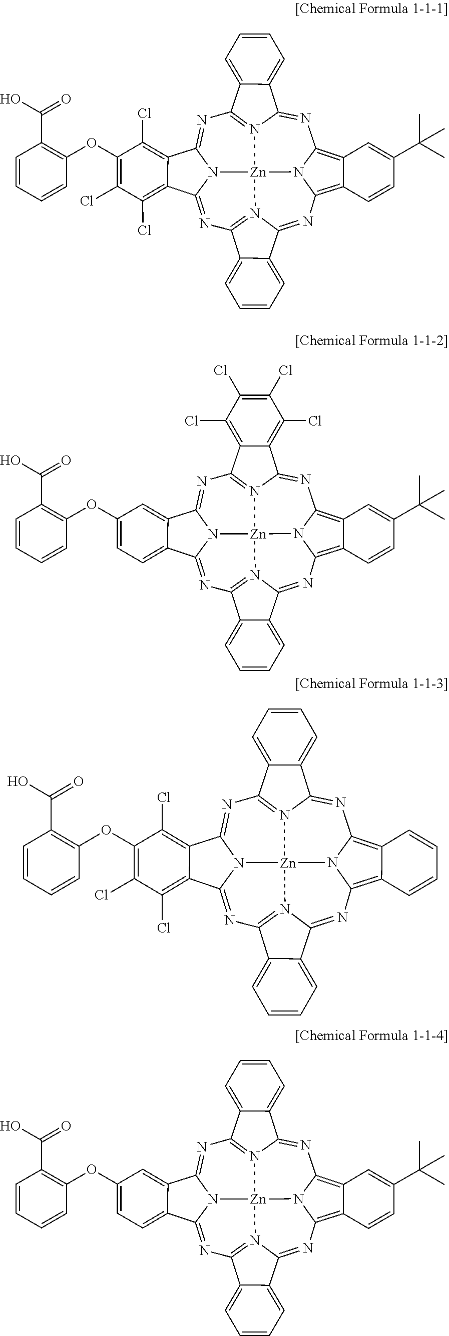

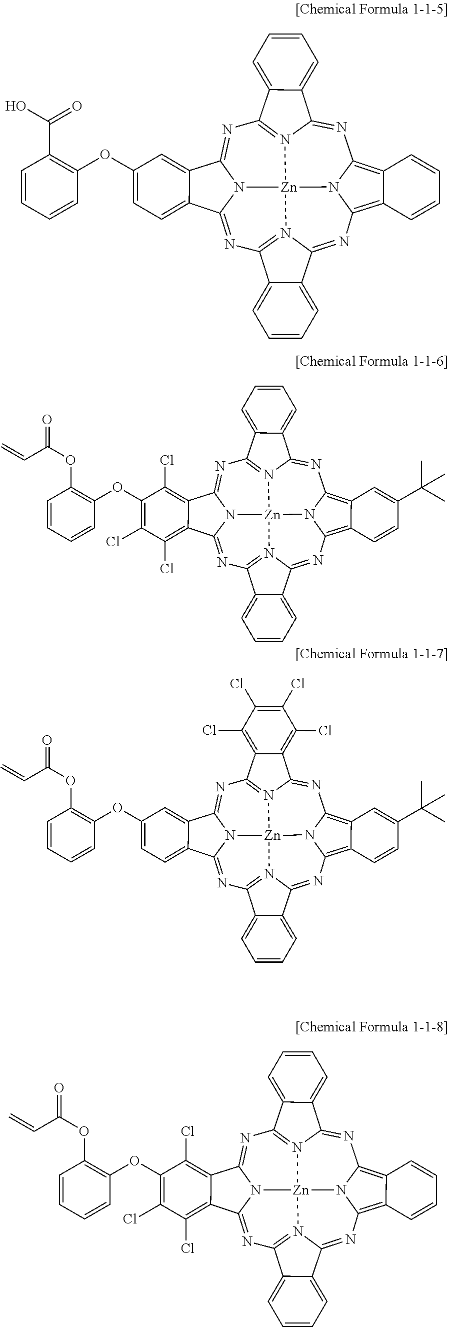

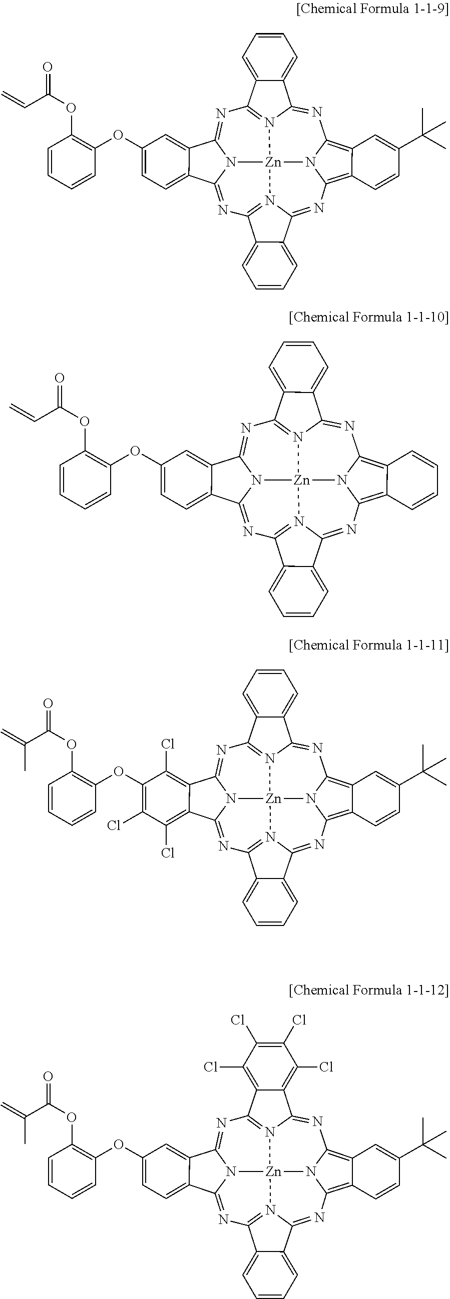

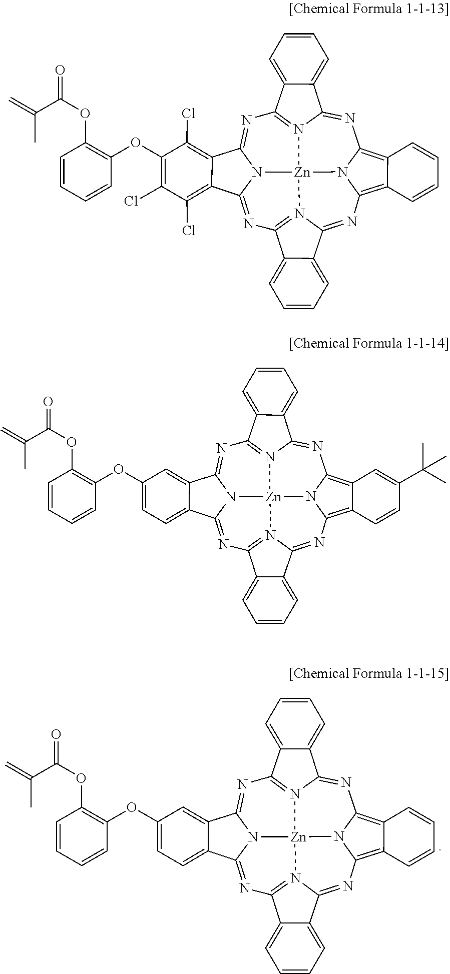

As described above, the additive represented by Chemical Formula 1 may have a phthalocyanine parent moiety as an auxochromophore (dye) that expresses blue, and may further improve a coloring power, contrast ratio, patternability, and the like of the photosensitive resin composition.

In an implementation, the additive represented by Chemical Formula 1 may have a maximum absorption wavelength (λₘₐₓ) of about 580 nm to about 700 nm.

The additive represented by Chemical Formula 1 may be included in an amount of about 0.01 wt % to about 5 wt %, e.g., about 0.1 wt % to about 3 wt %, or about 0.1 wt % to about 0.5 wt %, based on a total weight of the photosensitive resin composition.

In an implementation, a weight ratio of the additive represented by Chemical Formula 1 and the pigment may be about 1:1 to about 1:5, e.g., about 1:1 to about 1:4 or about 1:2 to about 1:4.

Within each of the above ranges, the dispersibility and dispersion stability of the photosensitive resin composition according to the embodiment may be improved while improving coloring power, contrast ratio, patternability, or the like.

The colorant may include a pigment, and the pigment may include green pigment, yellow pigment, blue pigment, red pigment, violet pigment, black pigment, etc.

The green pigment may include, e.g., C.I. Green Pigment 7, C.I. Green Pigment 36, C.I. Green Pigment 58, C.I. Green Pigment 59 or the like in the color index, which may be used alone or in a mixture of two or more.

The yellow pigment may include, e.g., an isoindoline pigment such as C.I. Yellow Pigment 185, C.I. Yellow Pigment 139, or the like, a quinophthalone pigment such as C.I. Yellow Pigment 138, a nickel complex pigment such as C.I. Yellow Pigment 150, or the like in the color index, which may be used alone or in a mixture of two or more.

The blue pigment may include, e.g., copper phthalocyanine pigments such as C.I. Blue Pigment 15:6, C.I. Blue Pigment 15, C.I. Blue Pigment 15:1, C.I. Blue Pigment 15:2, C.I. Blue Pigment 15:3, C.I. Blue Pigment 15:4, C.I. Blue Pigment 15:5, C.I. Blue Pigment 15:6, C.I. Blue Pigment 16, or the like in the color index, which may be used alone or in a mixture of two or more.

The red pigment may include, e.g., C.I. Red Pigment 254, C.I. Red Pigment 255, C.I. Red Pigment 264, C.I. Red Pigment 270, C.I. Red Pigment 272, C.I. Red Pigment 177, C.I. Red Pigment 89, or the like in the color index, which may be used alone or in a mixture of two or more.

The violet pigment may include, e.g., C.I. Violet Pigment 23 (V.23), C.I. Violet Pigment 29, Dioxazine Violet, First Violet B, Methyl Violet Lake, Indanethrene Brilliant Violet, or the like in the color index, which may be used alone or in a mixture of two or more.

The black pigment may include, e.g., aniline black, perylene black, titanium black, carbon black, or the like in the color index, which may be used alone or in a mixture of two or more.

The pigments may be used alone or in a mixture of two or more. In an implementation, the pigment may be a green pigment, a yellow pigment, or a mixture thereof.

The pigment may be included in the photosensitive resin composition for a color filter in the form of a dispersion. In addition to the pigment and the additive, this pigment dispersion may further include a dispersion resin, a dispersion solvent, a dispersant, etc. A content (PWC) of the pigment may be about 5 wt % to about 20 wt %, for example about 8 wt % to about 15 wt % based on a total amount of the pigment dispersion.

The dispersion solvent for the pigment dispersion may include, e.g., ethylene glycol acetate, 2-ethoxyethanol, propylene glycol methyl ether acetate, ethyl lactate, polyethylene glycol, cyclohexanone, propylene glycol methyl ether, or the like. In an implementation, the solvent may include, e.g., propylene glycol methyl ether acetate.

An acrylic-based dispersion resin may be used as the dispersion resin, which may not only improve the stability of the pigment dispersion but may also improve the patternability of the pixel. The dispersion resin may have a weight average molecular weight of about 10,000 to about 20,000 g/mol and an acid value of about 80 to about 200 KOHmg/g.

The dispersant may help the pigment to be uniformly dispersed in the dispersion, and nonionic, anionic or cationic dispersants may be used, respectively. In an implementation, polyalkylene glycol or its ester, polyoxy alkylene, a polyhydric alcohol ester alkylene oxide adduct, an alcohol alkylene oxide adduct, sulfonic acid ester, sulfonic acid salt, carboxylic acid ester, carboxylic acid salt, alkyl amide alkylene oxide adduct, an alkylamine, or the like may be used, and these may be used alone or in combination of two or more.

The colorant may further include a metal complex dye.

The metal complex dye may be a compound having maximum absorbance in the wavelength range of 200 nm to 650 nm, and if the compound were to have absorbance in the above range in order to match the color coordinates to the combination of dyes, the metal complex dye of all colors that dissolves in an organic solvent may be used.

In an implementation, the metal complex dye may be a green dye having maximum absorbance in a wavelength range of 530 nm to 680 nm, a yellow dye having maximum absorbance in a wavelength range of 200 nm to 400 nm, an orange dye having a maximum absorbance in a wavelength range of 300 nm to 500 nm, a red dye having maximum absorbance in a wavelength range of 500 nm to 650 nm, or a combination thereof.

The metal complex dye may be a direct dye, an acidic dye, a basic dye, an acidic mordant dye, a sulfide dye, a reduction dye, an azoic dye, a dispersion dye, a reactive dye, an oxidation dye, an oil-soluble dye, an azo dye, an anthraquinone dye, an indigoid dye, a carbonium ion dye, a phthalocyanine dye, a nitro dye, a quinoline dye, a cyanine dye, a polymethine dye, or a combination thereof.

The metal complex dye may include a metal ion of, e.g., Mg, Ni, Cu, Co, Zn, Cr, Pt, Pd, or Fe.

The metal complex dye may be a complex, e.g., C.I. Solvent Dye such as C.I. Solvent Green 1, 3, 4, 5, 7, 28, 29, 32, 33, 34, 35, or the like; C.I. Acid Dye such as C.I. Acid Green 1, 3, 5, 6, 7, 8, 9, 11, 13, 14, 15, 16, 22, 25, 27, 28, 41, 50, 50:1, 58, 63, 65, 80, 104, 105, 106, 109, or the like; C.I. Direct Dye such as C.I. Direct Green 25, 27, 31, 32, 34, 37, 63, 65, 66, 67, 68, 69, 72, 77, 79, 82, or the like; C.I. Basic Dye such as C.I. Basic Green 1, or the like; C.I. Mordant Dye such as C.I. Mordant Green 1, 3, 4, 5, 10, 13, 15, 19, 21, 23, 26, 29, 31, 33, 34, 35, 41, 43, 53, or the like; C.I. Green pigments such as Pigment Green 7, 36, 58, or the like; Solvent Yellow 19, Solvent Yellow 21, Solvent Yellow 25, Solvent Yellow 79, Solvent Yellow 82, Solvent Yellow 88, Solvent Orange 45, Solvent Orange 54, Solvent Orange 62, Solvent Orange 99, Solvent Red 8, Solvent Red 32, Solvent Red 109, Solvent Red 112, Solvent Red 119, Solvent Red 124, Solvent Red 160, Solvent Red 132, or Solvent Red 218, and the metal ion.

The metal complex dye may have a solubility of greater than or equal to about 5, e.g., about 5 to about 10, in a solvent used in the photosensitive resin composition according to some embodiments. The solubility may be obtained by an amount (g) of the dye dissolved in 100 g of the solvent. Within the above ranges, compatibility with other components constituting the photosensitive resin composition according to some embodiments and coloring power may be secured, and precipitation of the dye may be prevented.

Within the above ranges, it may be usefully used for color filters such as LCDs and LEDs that express high luminance and high contrast ratio in a desired color coordinate.

The metal complex dye may be included in an amount of about 0.01 wt % to about 1 wt %, e.g., about 0.01 wt % to about 0.5 wt % based on a total weight of the photosensitive resin composition. Within the above ranges, high luminance and contrast ratio may be exhibited in a desired color coordinate.

In an implementation, dye and the pigment may be mixed and used, e.g., in a weight ratio of about 0.1:99.9 to about 99.9:0.1 or about 1:9 to about 9:1. Within the above weight ratio ranges, chemical resistance and maximum absorption wavelength may be controlled within an appropriate range, and high luminance and contrast ratio may be exhibited in a desired color coordinate.

The colorant may be included in an amount of about 5 wt % to about 50 wt %, e.g., about 6 wt % to about 40 wt %, or about 7 wt % to about 30 wt % based on a total solid content of the photosensitive resin composition. Within the above ranges, a coloring effect and developability may be improved.

### (B) Photopolymerizable Compound

The photopolymerizable compound may include, e.g., a mono-functional or multi-functional ester of (meth)acrylic acid including at least one ethylenic unsaturated double bond.

The photopolymerizable compound may cause sufficient polymerization during exposure in a pattern-forming process and form a pattern having excellent heat resistance, light resistance, and chemical resistance due to the ethylenic unsaturated double bond.

Examples of the photopolymerizable compound may include ethylene glycol di(meth)acrylate, diethylene glycol di(meth)acrylate, triethylene glycol di(meth)acrylate, propylene glycol di(meth)acrylate, neopentyl glycol di(meth)acrylate, 1,4-butanediol di(meth)acrylate, 1,6-hexanediol di(meth)acrylate, bisphenol A di(meth)acrylate, pentaerythritol di(meth)acrylate, pentaerythritol tri(meth)acrylate, pentaerythritol tetra(meth)acrylate, pentaerythritol hexa(meth)acrylate, dipentaerythritol di(meth)acrylate, dipentaerythritol tri(meth)acrylate, dipentaerythritol penta(meth)acrylate, dipentaerythritol hexa(meth)acrylate, bisphenol A epoxy(meth)acrylate, ethylene glycol monomethylether (meth)acrylate, trimethylol propane tri(meth)acrylate, tris(meth)acryloyloxyethyl phosphate, novolacepoxy (meth)acrylate, and the like.

Commercially available examples of the photopolymerizable compound may be as follows. The mono-functional (meth)acrylic acid ester may include Aronix M-101®, Aronix M-111®, Aronix M-114® (Toagosei Chemistry Industry Co., Ltd.); KAYARAD TC-110S®, KAYARAD TC-120S® (Nippon Kayaku Co., Ltd.); V-158®, V-2311® (Osaka Organic Chemical Ind., Ltd.), and the like. Examples of a difunctional (meth)acrylic acid ester may include Aronix M-210®, Aronix M-240®, Aronix M-6200® (Toagosei Chemistry Industry Co., Ltd.), KAYARAD HDDA®, KAYARAD HX-220®, KAYARAD R-604® (Nippon Kayaku Co., Ltd.), V-260®, V-312®, V-335 HP® (Osaka Organic Chemical Ind., Ltd.), and the like. Examples of a tri-functional (meth)acrylic acid ester may include Aronix M-309®, Aronix M-400®, Aronix M-405®, Aronix M-450®, Aronix M-7100®, Aronix M-8030®, Aronix M-8060® (Toagosei Chemistry Industry Co., Ltd.); KAYARAD TMPTA®, KAYARAD DPCA-20®, KAYARAD DPCA-30®, KAYARAD DPCA-60®, KAYARAD DPCA-120® (Nippon Kayaku Co., Ltd.); V-295®, V-300®, V-360®, V-GPT®, V-3PA®, V-400® (Osaka Yuki Kayaku Kogyo Co. Ltd.), and the like. These may be used alone or as a mixture of two or more.

The photopolymerizable compound may be used by treating it with an acid anhydride to provide better developability.

The photopolymerizable compound may be included in an amount of about 1 wt % to about 30 wt %, e.g., about 5 wt % to about 25 wt % or about 15 wt % to about 25 wt % based on a total weight of the photosensitive resin composition. Within the above ranges, sufficient curing occurs during exposure to light in the pattern formation process, resulting in excellent reliability and excellent developability in an alkaline developer.

### (C) Photopolymerization Initiator

The photopolymerization initiator may be an initiator suitably used in photosensitive resin compositions, e.g., an acetophenone-based compound, a benzophenone compound, a thioxanthone compound, a benzoin compound, a triazine compound, an oxime compound, or a combination thereof.

Examples of the acetophenone compound may include 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and the like.

Examples of the benzophenone compound may include benzophenone, benzoyl benzoate, benzoyl methyl benzoate, 4-phenyl benzophenone, hydroxy benzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and the like.

Examples of the thioxanthone compound may include thioxanthone, 2-methylthioxanthone, isopropyl thioxanthone, 2,4-diethyl thioxanthone, 2,4-diisopropyl thioxanthone, 2-chlorothioxanthone, and the like.

Examples of the benzoin compound may include benzoin, benzoin methyl ether, benzoin ethyl ether, benzoin isopropyl ether, benzoin isobutyl ether, benzyldimethylketal, and the like.

Examples of the triazine compound may include 2,4,6-trichloro-s-triazine, 2-phenyl 4,6-bis(trichloromethyl)-s-triazine, 2-(3′, 4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloro methyl)-s-triazine, 2-biphenyl 4,6-bis(trichloro methyl)-s-triazine, bis(trichloromethyl)-6-styryl-s-triazine, 2-(naphthol-yl)-4,6-bis(trichloromethyl)-s-triazine, 2-(4-methoxynaphthol-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and the like.

Examples of the oxime compound may include an O-acyloxime-based compound, 2-(o-benzoyloxime)-1-[4-(phenylthio)phenyl]-1,2-octanedione, 1-(o-acetyloxime)-1-[9-ethyl-6-(2-methylbenzoyl)-9H-carbazol-3-yl]ethanone, O-ethoxycarbonyl-α-oxyamino-1-phenylpropan-1-one, and the like. Examples of the O-acyloxime-based compound may be 1,2-octanedione, 2-dimethylamino-2-(4-methylbenzyl)-1-(4-morpholin-4-yl-phenyl)-butan-1-one, 1-(4-phenylsulfanyl phenyl)-butane-1,2-dione2-oxime-O-benzoate, 1-(4-phenylsulfanyl phenyl)-octane-1,2-dione2-oxime-O-benzoate, 1-(4-phenylsulfanyl phenyl)-octan-1-oneoxime-O-acetate and 1-(4-phenylsulfanyl phenyl)-butan-1-oneoxime-O-acetate, and the like.

In an implementation, the photopolymerization initiator may include a carbazole compound, a diketone compound, a sulfonium borate compound, a diazo compound, an imidazole compound, a biimidazole compound, and a fluorene-based compound.

The photopolymerization initiator may be used with a photosensitizer capable of causing a chemical reaction by absorbing light and becoming excited and then, transferring its energy.

Examples of the photosensitizer may include tetraethylene glycol bis-3-mercapto propionate, pentaerythritol tetrakis-3-mercapto propionate, dipentaerythritol tetrakis-3-mercapto propionate, and the like.

The photopolymerization initiator may be included in an amount of about 0.1 wt % to about 10 wt %, e.g., about 1 wt % to about 5 wt % based on a total weight of the photosensitive resin composition. Within the above ranges, sufficient photopolymerization may occur during exposure in a pattern-forming process, excellent reliability may be realized, heat resistance, light resistance, and chemical resistance of patterns, resolution and close contacting properties may be improved, and decrease of transmittance due to a non-reaction initiator may be prevented.

### (D) Binder Resin

The binder resin may include, e.g., an acrylic binder resin.

The acrylic resin may be a copolymer of a first ethylenic unsaturated monomer and a second ethylenic unsaturated monomer that is copolymerizable therewith, and may be a resin including at least one acryl-based repeating unit.

The first ethylenic unsaturated monomer may be an ethylenic unsaturated monomer including at least one carboxyl group and examples of the monomer may include acrylic acid, methacrylic acid, maleic acid, itaconic acid, fumaric acid, or a combination thereof.

The first ethylenic unsaturated monomer may be included in an amount of about 5 wt % to about 50 wt %, e.g., about 10 wt % to about 40 wt % based on a total weight of the acrylic binder resin.

The second ethylenic unsaturated monomer may be an aromatic vinyl compound such as styrene, α-methylstyrene, vinyl toluene, vinylbenzylmethylether or the like; an unsaturated carboxylate ester compound such as methyl (meth)acrylate, ethyl (meth)acrylate, butyl (meth)acrylate, 2-hydroxyethyl (meth)acrylate, 2-hydroxy butyl (meth)acrylate, benzyl (meth)acrylate, cyclohexyl (meth)acrylate, phenyl(meth)acrylate, or the like; an unsaturated amino alkyl carboxylate ester compound such as 2-aminoethyl(meth)acrylate, 2-dimethylaminoethyl(meth)acrylate, or the like; a carboxylic acid vinyl ester compound such as vinyl acetate, vinyl benzoate, or the like; an unsaturated glycidyl carboxylate ester compound such as glycidyl(meth)acrylate, or the like; a vinyl cyanide compound such as (meth)acrylonitrile or the like; an unsaturated amide compound such as (meth)acrylamide, or the like; or the like, and may be used alone or as a mixture of two or more.

Examples of the acrylic resin may include a (meth)acrylic acid/benzylmethacrylate copolymer, a (meth)acrylic acid/benzylmethacrylate copolymer, a (meth)acrylic acid/benzylmethacrylate/styrene copolymer, a (meth)acrylic acid/benzylmethacrylate/2-hydroxyethylmethacrylate copolymer, a (meth)acrylic acid/benzylmethacrylate/styrene/2-hydroxyethylmethacrylate copolymer, and the like, and these may be used alone or as a mixture of two or more.

The binder resin may include an epoxy binder resin.

The binder resin may help improve heat resistance by further including an epoxy binder resin. The epoxy binder resin may include, e.g., a phenol novolac epoxy resin, a tetramethyl biphenyl epoxy resin, a bisphenol A epoxy resin, a bisphenol F epoxy resin, an alicyclic epoxy resin, or a combination thereof.

In an implementation, the binder resin including the epoxy binder resin may help secure dispersion stability of a colorant such as a pigment, and may help form a pixel having a desired resolution during a developing process.

The epoxy binder resin may be included in an amount of about 1 wt % to about 10 wt %, e.g., about 5 wt % to about 10 wt % based on a total weight of the binder resin. Within the above ranges, film residue ratio and chemical resistance may be greatly improved.

An epoxy equivalent weight of the epoxy-based resin may be about 150 g/eq to about 200 g/eq. Within the above range there may be an advantageous effect in improving a curing degree of the formed pattern and fixing the colorant in the structure in which the pattern is formed.

The binder resin may be dissolved in a solvent in a solid form to form a photosensitive resin composition. In an implementation, the binder resin in the solid form may be about 0.1 wt % to about 30 wt %, e.g., about 20 wt % to about 30 wt % based on a total weight of the binder resin solution dissolved in the solvent.

The binder resin may be included in an amount of about 1 wt % to about 20 wt %, e.g., about 5 wt % to about 15 wt %, or about 10 wt % to about 15 wt % based on a total solid content of the photosensitive resin composition. Within the above ranges, it is possible to obtain excellent surface smoothness due to excellent developability and improved crosslinking property during manufacture of the color filter.

### (E) Solvent

The solvent may be a material having compatibility with the colorant, the binder resin, the photopolymerizable compound, and the photopolymerization initiator but not reacting therewith.

Examples of the solvent may include alcohols such as methanol, ethanol, and the like; ethers such as dichloroethyl ether, n-butyl ether, diisoamyl ether, methylphenyl ether, tetrahydrofuran, and the like; glycol ethers such as ethylene glycol monomethylether, ethylene glycol monoethylether, and the like; Cellosolve acetates such as methyl Cellosolve acetate, ethyl Cellosolve acetate, diethyl Cellosolve acetate, and the like; Carbitols such as methylethyl Carbitol, diethyl Carbitol, diethylene glycol monomethylether, diethylene glycol monoethylether, diethylene glycol dimethylether, diethylene glycol methylethylether, diethylene glycol diethylether, and the like; propylene glycol alkylether acetates such as propylene glycol monomethylether acetate, propylene glycol propylether acetate, and the like; aromatic hydrocarbons such as toluene, xylene and the like; ketones such as methylethylketone, cyclohexanone, 4-hydroxy-4-methyl-2-pentanone, methyl-n-propylketone, methyl-n-butylketone, methyl-n-amylketone, 2-heptanone, and the like; saturated aliphatic monocarboxylic acid alkyl esters such as ethyl acetate, n-butyl acetate, isobutyl acetate, and the like; lactate esters such as methyl lactate, ethyl lactate, and the like; oxy acetic acid alkyl esters such as oxy methyl acetate, oxy ethyl acetate, butyl oxyacetate, and the like; alkoxy acetic acid alkyl esters such as methoxy methyl acetate, methoxy ethyl acetate, methoxy butyl acetate, ethoxy methyl acetate, ethoxy ethyl acetate, and the like; 3-oxy propionic acid alkyl esters such as 3-oxy methyl propionate, 3-oxy ethyl propionate, and the like; 3-alkoxy propionic acid alkyl esters such as 3-methoxy methyl propionate, 3-methoxy ethyl propionate, 3-ethoxy ethyl propionate, 3-ethoxy methyl propionate, and the like; 2-oxy propionic acid alkyl esters such as 2-oxy methyl propionate, 2-oxy ethyl propionate, 2-oxy propyl propionate, and the like; 2-alkoxy propionic acid alkyl esters such as 2-methoxy methyl propionate, 2-methoxy ethyl propionate, 2-ethoxy ethyl propionate, 2-ethoxy methyl propionate, and the like; 2-oxy-2-methyl propionic acid esters such 2-oxy-2-methyl methyl propionate, 2-oxy-2-methyl ethyl propionate, and the like, monooxy monocarboxylic acid alkyl esters of 2-alkoxy-2-methyl alkyl propionates such as 2-methoxy-2-methyl methyl propionate, 2-ethoxy-2-methyl ethyl propionate, and the like; esters such as 2-hydroxy ethyl propionate, 2-hydroxy-2-methyl ethyl propionate, hydroxy ethyl acetate, 2-hydroxy-3-methyl methyl butanoate, and the like; ketonate esters such as ethyl pyruvate, and the like. In an implementation, high boiling point solvent such as N-methylformamide, N,N-dimethylformamide, N-methylformanilide, N-methylacetamide, N,N-dimethylacetamide, N-methylpyrrolidone, dimethylsulfoxide, benzylethylether, dihexylether, acetylacetone, isophorone, caproic acid, caprylic acid, 1-octanol, 1-nonanol, benzylalcohol, benzyl acetate, ethyl benzoate, diethyl oxalate, diethyl maleate, γ-butyrolactone, ethylene carbonate, propylene carbonate, phenyl Cellosolve acetate, or the like may be also used.

In an implementation, considering compatibility and reactivity, the solvent may include, e.g., propylene glycol monomethyl ether acetate (PGMEA), n-butyl acetate (n-BA), and ethylene glycol dimethyl ether, or a combination thereof.

The solvent may be included in a balance amount, e.g., about 1 wt % to about 30 wt %, or about 10 wt % to about 20 wt %, based on a total weight of the photosensitive resin composition. Within the above ranges, the photosensitive resin composition has excellent applicability and a coating film with excellent flatness may be obtained.

### (F) Other Additives

In an implementation, the photosensitive resin composition may further include an additive selected from, e.g., malonic acid; 3-amino-1,2-propanediol; a coupling agent containing a vinyl group or a (meth)acryloxy group; or a radical polymerization initiator, in order to help prevent stains or spots during the coating, to help improve leveling performance, and to help prevent the generation of undeveloped residues.

The additives may be adjusted according to desired physical properties.

The coupling agent may be a silane coupling agent, and examples of the silane coupling agent may include trimethoxysilyl benzoic acid, γ methacryl oxypropyl trimethoxysilane, vinyl triacetoxysilane, vinyl trimethoxysilane, γ isocyanate propyl triethoxysilane, γ glycidoxy propyl trimethoxysilane, ß epoxycyclohexyl) ethyltrimethoxysilane, which may be used alone or in mixture of 2 or more types.

The silane coupling agent may be included, e.g., in an amount of 0.01 part by weight to 1 part by weight based on 100 parts by weight of the photosensitive resin composition.

In an implementation, the photosensitive resin composition for a color filter may further include a surfactant, e.g., a fluorine surfactant.

Examples of the fluorine surfactant may include F-482, F-484, and F-478 of DIC Co., Ltd.

The surfactant may be included in an amount of 0.01 wt % to 5 wt %, e.g., 0.01 wt % to 2 wt % based on a total weight of the photosensitive resin composition. Within the above ranges, a problem in that foreign substances are generated after development may be avoided.

In an implementation, other additives, e.g., an antioxidant, a stabilizer, or the like may be added to the photosensitive resin composition within a range that does not impair physical properties.

### (Photosensitive Resin Layer, Color Filter, and Display Device)

Some example embodiments provide a photosensitive resin layer manufactured using the photosensitive resin composition according to some example embodiments.

The photosensitive resin layer of some example embodiments may be divided into a color positive photoresist composition and a color negative photoresist composition.

The photosensitive resin layer of some example embodiments may be a color negative photoresist. This may have the advantage that coloring caused by the photoresist may not occur and that light sensitivity may be relatively higher than that of positive photoresist.

Some embodiments may provide a color filter manufactured using the aforementioned photosensitive resin composition.

A method of manufacturing the color filter may be as follows.

The aforementioned photosensitive resin composition may be coated to form a photosensitive resin composition layer with a thickness of 0.5 um to 10 um on a glass substrate in a suitable method such as spin coating, roller coating, spray coating, or the like.

Subsequently, the substrate having the photosensitive resin composition layer may be radiated by light (or other radiation or energy) to form a pattern required for a color filter. The irradiation may be performed by using UV, an electron beam or an X-ray as a light source, and the UV may be irradiated, e.g., in a region of 190 nm to 450 nm or 200 nm to 400 nm. The irradiation may be performed by further using a photoresist mask. After performing the irradiation process in this way, the photosensitive resin composition layer exposed to the light source may be treated with a developer. In an implementation, a non-exposed region in the photosensitive resin composition layer may be dissolved and may form the pattern for a color filter. This process may be repeated as many times as the number of desired colors, obtaining a color filter having a desired pattern. In an implementation, if the image pattern obtained through development in the above process may be cured by reheating or irradiating an actinic ray thereinto, and crack resistance, solvent resistance, and the like may be improved.

According to some example embodiments, a display device including the aforementioned color filter is provided.

The display device may be a CMOS image sensor, a liquid crystal display device, a CMOS image sensor, or the like.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### (Preparation of Pigment Dispersion)

Each pigment dispersion of Preparation Examples 1 to 7 and Preparation Comparative Examples 1 to 3 was prepared to have a composition as shown in Table 1.

Each pigment dispersion was obtained by mixing the pigment, additive, dispersion resin, and solvent and pouring 300 parts by weight of zirconia beads (diameter: 0.4 μm) based 100 parts by weight of the mixture thereinto, dispersing them by shaking with a paint shaker for 3 hours, and removing the zirconia beads through filtration.

TABLE 1
(unit: wt %)

| | | Preparation | Preparation | Preparation | Preparation | Preparation |
|---|---|---|---|---|---|---|
| | | Example 1 | Example 2 | Example 3 | Example 4 | Example 5 |
| A-1-1 (pigment) | | 12 | 12 | 12 | 12 | 12 |
| A-1-2 | Additive 1 | 4 | — | — | — | — |
| (additive) | Additive 2 | — | 4 | — | — | — |
| | Additive 3 | — | — | 4 | — | — |
| | Additive 4 | — | — | — | 4 | — |
| | Additive 5 | — | — | — | — | 4 |
| | Additive 6 | — | — | — | — | — |
| | Additive 7 | — | — | — | — | — |
| | Additive 8 | — | — | — | — | — |

| | | | | | |
|---|---|---|---|---|---|
| A-1-3 (dispersion resin) | 4 | 4 | 4 | 4 | 4 |
| A-1-4 (dispersion solvent) | 80 | 80 | 80 | 80 | 80 |

(unit: wt %)

| | | | | Preparation | Preparation | Preparation |
|---|---|---|---|---|---|---|
| | | Preparation | Preparation | Comparative | Comparative | Comparative |
| | | Example 6 | Example 7 | Example 1 | Example 2 | Example 3 |
| A-1-1 (pigment) | | 12 | 12 | 16 | 12 | — |
| A-1-2 | Additive 1 | — | — | — | — | 16 |
| (additive) | Additive 2 | — | — | — | — | — |
| | Additive 3 | — | — | — | — | — |
| | Additive 4 | — | — | — | — | — |
| | Additive 5 | — | — | — | — | — |
| | Additive 6 | 4 | — | — | — | — |
| | Additive 7 | — | 4 | — | — | — |
| | Additive 8 | — | — | | 4 | — |

| | | | | | |
|---|---|---|---|---|---|
| A-1-3 (dispersion resin) | 4 | 4 | 4 | 4 | 4 |
| A-1-4 (dispersion solvent) | 80 | 80 | 80 | 80 | 80 |

The materials used in Table 1 above are as follows.

### A-1-1 (Pigment)

C.I. PIGMENT Green 58

### A-1-2 (Additive)

Additive 1: Compound represented by Chemical Formula 1-1-1
Additive 2: Compound represented by Chemical Formula 1-1-2
Additive 3: Compound represented by Chemical Formula 1-1-3
Additive 4: Compound represented by Chemical Formula 1-1-4
Additive 5: Compound represented by Chemical Formula 1-1-5
Additive 6: Compound represented by Chemical Formula 1-1-6
Additive 7: Compound represented by Chemical Formula Jan. 1, 2011
Additive 8: Compound represented by Chemical Formula A

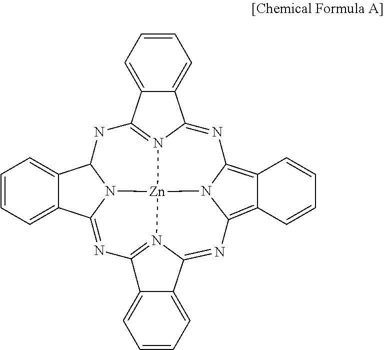

### A-1-3 (Acryl-Based Dispersion Resin)

RY-92 (manufacturer: Showa Denko, molecular weight: 5,900 g/mol, acid value: 33 KOHmg/g, double bond equivalent: 350 g/mol)

### A-1-4 (Dispersion Solvent)

propylene glycol monomethylether acetate (PGMEA)

### (Preparation of Photosensitive Resin Composition)

The photosensitive resin compositions of Examples 1 to 7 and Comparative Examples 1 to 3 were prepared by mixing the compositions shown in Table 2.

Each photosensitive color resin compositions was prepared by mixing the pigment dispersion, yellow pigment, green pigment, photopolymerizable monomer, photopolymerization initiator, binder resin, and solvent.

TABLE 2
(unit: wt %)

| | | Example 1 | Example 2 | Example 3 | Example 4 | Example 5 | Example 6 |
|---|---|---|---|---|---|---|---|
| A (colorant) | Preparation Example 1 | 10 | — | — | — | — | — |
| | Preparation Example 2 | — | 10 | — | — | — | — |
| | Preparation Example 3 | — | — | 10 | — | — | — |
| | Preparation Example 4 | — | — | — | 10 | — | — |
| | Preparation Example 5 | — | — | — | — | 10 | — |
| | Preparation Example 6 | — | — | — | — | — | 10 |
| | Preparation Example 7 | — | — | — | — | — | — |
| | Preparation Comparative | — | — | — | — | — | — |
| | Example 1 | | | | | | |
| | Preparation Comparative | — | — | — | — | — | — |
| | Example 2 | | | | | | |
| | Preparation Comparative | — | — | — | — | — | — |
| | Example 3 | | | | | | |
| | A-2 | 18 | 18 | 18 | 18 | 18 | 18 |
| | A-3 | 22 | 22 | 22 | 22 | 22 | 22 |
| B (photopolymerizable compound) | | 19 | 19 | 19 | 19 | 19 | 19 |
| C (photopolymerization initiator) | | 3.2 | 3.2 | 3.2 | 3.2 | 3.2 | 3.2 |
| D (binder resin) | | 12 | 12 | 12 | 12 | 12 | 12 |
| E (solvent) | | 15 | 15 | 15 | 15 | 15 | 15 |
| F (other | F-1 | 0.5 | 0.5 | 0.5 | 0.5 | 0.5 | 0.5 |
| additives) | F-2 | 0.3 | 0.3 | 0.3 | 0.3 | 0.3 | 0.3 |

(unit: wt %)

| | | | Comparative | Comparative | Comparative |
|---|---|---|---|---|---|
| | | Example 7 | Example 1 | Example 2 | Example 3 |
| A (colorant) | Preparation Example 1 | — | — | — | — |
| | Preparation Example 2 | — | — | — | — |
| | Preparation Example 3 | — | — | — | — |
| | Preparation Example 4 | — | — | — | — |
| | Preparation Example 5 | — | — | — | — |
| | Preparation Example 6 | — | — | — | — |
| | Preparation Example 7 | 10 | — | — | — |
| | Preparation Comparative | — | 10 | — | — |
| | Example 1 | | | | |
| | Preparation Comparative | — | — | 10 | — |
| | Example 2 | | | | |
| | Preparation Comparative | — | — | — | 10 |
| | Example 3 | | | | |
| | A-2 | 18 | 18 | 18 | 18 |
| | A-3 | 22 | 22 | 22 | 22 |
| B (photopolymerizable compound) | | 19 | 19 | 19 | 19 |
| C (photopolymerization initiator) | | 3.2 | 3.2 | 3.2 | 3.2 |
| D (binder resin) | | 12 | 12 | 12 | 12 |
| E (solvent) | | 15 | 15 | 15 | 15 |
| F (other | F-1 | 0.5 | 0.5 | 0.5 | 0.5 |
| additives) | F-2 | 0.3 | 0.3 | 0.3 | 0.3 |

The materials used in Table 2 above are as follows.

### A (Colorant)

Each pigment dispersion of Preparation Examples 1 to 7 and Comparative Preparation Examples 1 to 3
A-2: C.I. PIGMENT Yellow 185 Y185
A-3: C.I. PIGMENT Green 58 G58

### B (Photopolymerizable Compound)

dipentaerythritolhexaacrylate (DPHA, manufacturer: Nippon Kayaku Co., Ltd.)

### C (Photopolymerization Initiator)

Oxime-based initiator SPI-03 (manufacturer: Samyang Corporation)

### D (Binder Resin)

RY-92 (manufacturer: Showa Denko, molecular weight: 5,900 g/mol, acid value: 33 KOHmg/g, double bond equivalent: 350 g/mol)

### E (Solvent)

propylene glycol monomethylether acetate (PGMEA)

### F (Other Additives)

F-1: radical polymerization initiator

### KBM-503 (Shin-Etsu Silicone)

F-2: leveling agent
F-556 (manufacturer: DIC Co., Ltd.)

### Evaluation Example 1: Dispersibility and Dispersion Stability

Each photosensitive resin composition of Examples 1 to 7 and Comparative Examples 1 to 3 was measured with respect to a solid particle diameter by using a dynamic light scattering analyzer, and the results are shown in Table 3.

In addition, each photosensitive resin composition of Examples 1 to 7 and Comparative Examples 1 to 3 were measured with respect to viscosity before and after being stored at 23° C. for 1 week at 5 rpm (rpm where Torque value became 50% to 100%) by using Brookfield DV-II Pro viscometer and CPE-52 Spindle at 25° C., and the results are shown in Table 3.

TABLE 3

| | Solid particle diameter (nm) | | | Viscosity (cPs) | | |
|---|---|---|---|---|---|---|
| | After | | | After | | |
| | prepar- | After 1 | Differ- | prepar- | After 1 | Differ- |
| | ation | week | ence | ation | week | ence |
| Example 1 | 67.1 | 69.0 | +1.9 | 5.23 | 5.31 | +0.08 |
| Example 2 | 68.9 | 70.1 | +0.2 | 5.17 | 5.19 | +0.02 |
| Example 3 | 66.2 | 67.8 | +1.6 | 5.33 | 5.31 | −0.02 |
| Example 4 | 67.5 | 67.1 | −0.4 | 5.41 | 5.48 | +0.07 |
| Example 5 | 69.1 | 71.2 | +2.1 | 5.11 | 5.13 | +0.02 |
| Example 6 | 64.5 | 66.8 | +2.3 | 5.29 | 5.30 | +0.01 |
| Example 7 | 67.2 | 67.9 | +0.7 | 5.18 | 5.26 | +0.08 |
| Comparative | 61.1 | 72.5 | +11.4 | 5.55 | 5.81 | +0.26 |
| Example 1 | | | | | | |
| Comparative | 67.2 | 81.2 | +14.0 | 5.37 | 6.20 | +0.83 |
| Example 2 | | | | | | |
| Comparative | 63.1 | 68.4 | +5.3 | 5.69 | 5.81 | +0.12 |
| Example 3 | | | | | | |

Referring to Table 3, the photosensitive resin compositions of Examples 1 to 7, compared with the photosensitive resin compositions of Comparative Examples 1 to 3, exhibited small differences in the viscosity as well as in the solid particle diameter before and after stored for one week.

### Evaluation Example 2: Coloring Power and Contrast Ratio

Each photosensitive resin composition of Examples 1 to 7 and Comparative Examples 1 to 3 was coated to be 1 to 3 μm thick on a 1 mm-thick glass substrate, which was degreased and washed, and then, dried on a hot plate at 90° C. for 2 minutes to obtain a film. The film was exposed to light by using a high-pressure mercury lamp having a main wavelength of 365 nm and then, dried in a 200° C. forced convection drying furnace for 5 minutes to obtain a color filter specimen.

In order to evaluate it as a pixel layer, each color filter specimen was measured with respect to a color coordinate (x, y), luminance (Y), and contrast ratios by using a spectrophotometer (MCPD3000, Otsuka Electronics Co., Ltd.), and the results are shown in Table 4.

TABLE 4

| | | |
|---|---|---|
| Color coordinate | Luminance | Contrast |

| | x | y | (Y) | ratio |
|---|---|---|---|---|
| Example 1 | 0.3251 | 0.609 | 61.32 | 24513 |
| Example 2 | 0.3260 | 0.609 | 61.51 | 22175 |
| Example 3 | 0.3255 | 0.609 | 60.57 | 23819 |
| Example 4 | 0.3263 | 0.609 | 62.14 | 21974 |
| Example 5 | 0.3253 | 0.609 | 60.71 | 23318 |
| Example 6 | 0.3251 | 0.609 | 61.87 | 22291 |
| Example 7 | 0.3257 | 0.609 | 61.90 | 24127 |
| Comparative | 0.3250 | 0.609 | 59.48 | 18910 |
| Example 1 | | | | |
| Comparative | 0.3281 | 0.609 | 57.64 | 20087 |
| Example 2 | | | | |
| Comparative | 0.3261 | 0.609 | 58.10 | 19183 |
| Example 3 | | | | |

Referring to Table 4, the color filter specimens of Examples 1 to 7, compared with the color filter specimens of Comparative Examples 1 to 3, exhibited improved coloring power, luminance, and contrast ratios.

### Evaluation Example 3: Patternability

Each of the photosensitive resin compositions of Example 1 and Comparative Examples 1 and 3 were coated on an 8-inch silicon wafer by using a coater (Mikasa Co., Ltd.) at a rpm suitable for securing a predetermined thickness (1.5 um) for each sample. Subsequently, prebaking at about 100° C. on a hot plate, exposure to light for 1000 msec pattern by using an i-line stepper (Nikon Inc.), and development for patternability proceeded. Herein, a TMAH solution (ENF Technology Co., Ltd.) was used as a developer, and a pattern shape was completed by baking on a 230° C. hot plate for 5 minutes. The pattern was measured with respect to 2.8 um pattern CD by using CD-SEM (Hitachi, Ltd.).

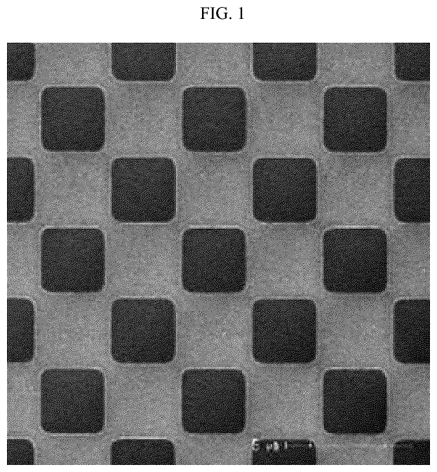

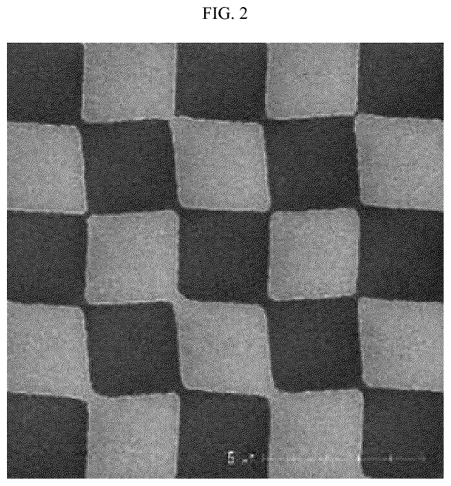

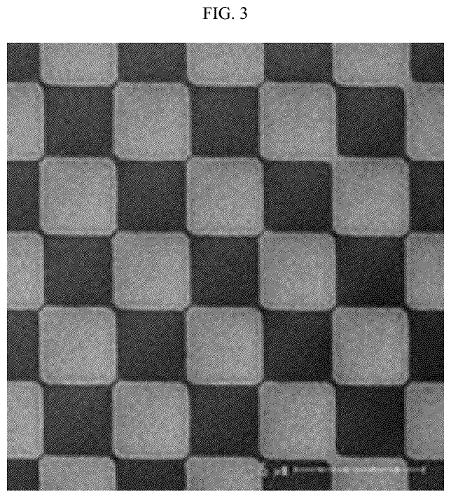

FIGS. 1 to 3 show each 2.8 um pattern CD of Example 1 and Comparative Examples 1 and 3, respectively. Referring to FIGS. 1 to 3, the color filter specimen of Example 1 exhibited improved patternability, compared with the color filter specimens of Comparative Examples 1 and 3.

In summary, when the additive represented by Chemical Formula 1 was used, a photosensitive resin composition exhibiting excellent coloring power and contrast ratio as well as having high dispersibility and dispersion stability of pigments when implementing a color filter was realized.

Herein, Examples 1 to 7 are representatively exemplified, but it may also be possible to control dispersibility, dispersion stability, coloring power, contrast ratio, patterning, etc. to a desired level by adjusting within the scope of some example embodiments.

By way of summation and review, among the solid image sensors, a CMOS image sensors (CIS) may be a collection of pixels as a non-memory semiconductor converting an image received by a camera into digital signals, such as a color filter, a photodiode, an amplifier, and the like. In the CIS, external light passing through the color filter may be converted into color image data (R, G, B data) and processed into the signals to be driven into a display device.

The color filter for the CIS may be manufactured by using a pigment-type photosensitive resin composition. In an implementation, the color filter manufactured by using the pigment-type photosensitive resin composition may have limitations in terms of luminance and a contrast ratio due to a pigment particle size.

On the other hand, in order to increase quality of the CIS image, it may be necessary to maximize the number of the pixels as well as make the pixel size of the color filter, or the like small and thin. As the color filter is down-sized and thinned, PWC (pigment weight concentration) may be increased. In particular, since a negative-type color filter may be required of a high contrast, transmittance, and color characteristics, in order to secure these, PWC should be further increased. In an implementation, if PWC is excessively increased, there may be a problem of deteriorating regularity and linearity of a color filter pattern.

In an implementation, in order to achieve the regularity and linearity of the color filter pattern, while down-sizing and thinning the color filter, a material having excellent coloring power and contrast ratio as well as high dispersibility and dispersion stability is required.

One or more embodiments may provide a photosensitive resin composition that has high dispersibility and dispersion stability, and excellent coloring power, contrast ratio, patternability, and the like when implementing color filters and CIS.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A photosensitive resin composition, comprising:
a colorant;
a photopolymerizable compound;
a photopolymerization initiator;
a binder resin; and
a solvent;
wherein:
the colorant includes a pigment and an additive represented by Chemical Formula 1: 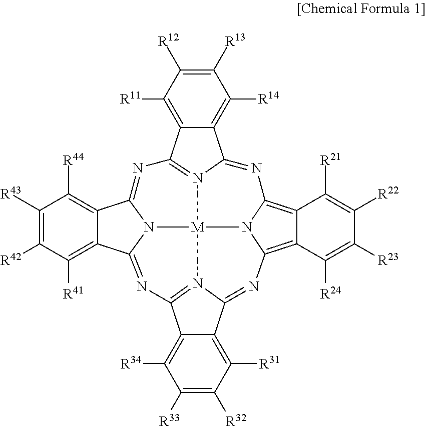
in Chemical Formula 1,
M is Zn or Cu;
R¹¹ to R¹⁴, R²¹ to R²⁴, and R³¹ to R³⁴ are each independently a hydrogen atom, a halogen atom, a hydroxy group, or a substituted or unsubstituted C1 to C20 alkyl group;
R⁴¹ to R⁴⁴ are each independently a halogen atom or a substituent represented by *-L¹-L²-A, provided that at least one of R⁴¹ to R⁴⁴ is a substituent represented by *-L¹-L²-A;
L¹ is *—O—* or *—S—*;
L² is a single bond or a substituted or unsubstituted C6 to C20 arylene group; and
A is a carboxyl group or a meth (acrylate) group.

2. The photosensitive resin composition as claimed in claim 1, wherein R¹¹ to R¹⁴ are all hydrogen atoms or halogen atoms.

3. The photosensitive resin composition as claimed in claim 1, wherein one of R²¹ to R²⁴ is a substituted or unsubstituted C1 to C20 alkyl group, and the rest are all hydrogen atoms.

4. The photosensitive resin composition as claimed in claim 1, wherein R³¹ to R³⁴ are all hydrogen atoms.

5. The photosensitive resin composition as claimed in claim 1, wherein one of R⁴¹ to R⁴⁴ is a substituent represented by *-L¹-L²-A; and the rest are all hydrogen atoms or all halogen atoms.

6. The photosensitive resin composition as claimed in claim 5, wherein L¹ is *—O—*.

7. The photosensitive resin composition as claimed in claim 5, wherein L² is a substituted or unsubstituted phenylene group.

8. The photosensitive resin composition as claimed in claim 1, wherein:
the substituent represented by *-L¹-L²-A is represented by Chemical Formula 2: 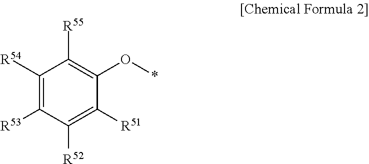
in Chemical Formula 2,
R⁵¹ to R⁵⁵ are each independently a hydrogen atom, a carboxyl group, or a meth(acrylate) group, provided that at least one of R⁵¹ to R⁵⁵ is a carboxyl group or a meth(acrylate) group.

9. The photosensitive resin composition as claimed in claim 1, wherein:
the additive is represented by Chemical Formula 1-1: 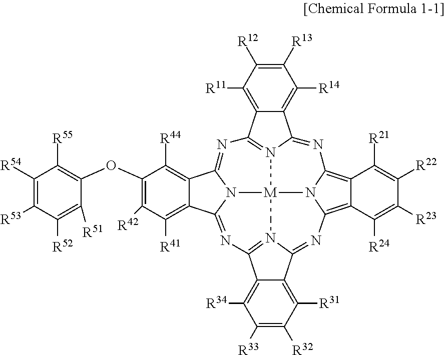
in Chemical Formula 1-1,
M is Zn or Cu;
R¹¹ to R¹⁴, R²¹ to R²⁴, and R³¹ to R³⁴ are each independently a hydrogen atom, a halogen atom, a hydroxy group, or a substituted or unsubstituted C1 to C20 alkyl group;
R⁴¹, R⁴², and R⁴⁴ are each independently a hydrogen atom or a halogen atom; and
R⁵¹ to R⁵⁵ are each independently a hydrogen atom, a carboxyl group, or a meth (acrylate) group, provided that at least one of R⁵¹ to R⁵⁵ is a carboxyl group or a meth (acrylate) group.

10. The photosensitive resin composition as claimed in claim 1, wherein the additive represented is a compound represented by one of the following Chemical Formulae:

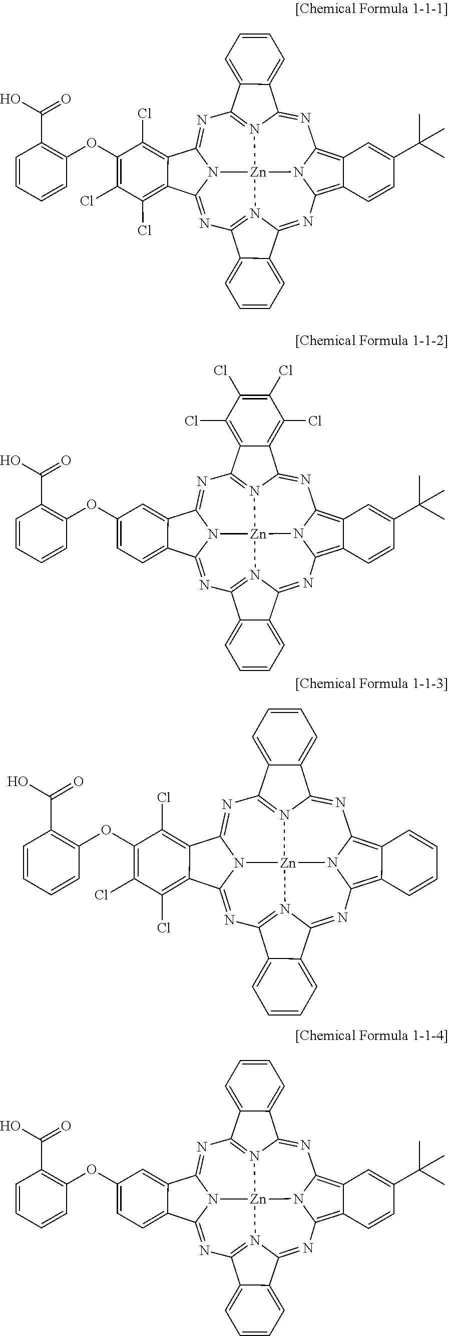

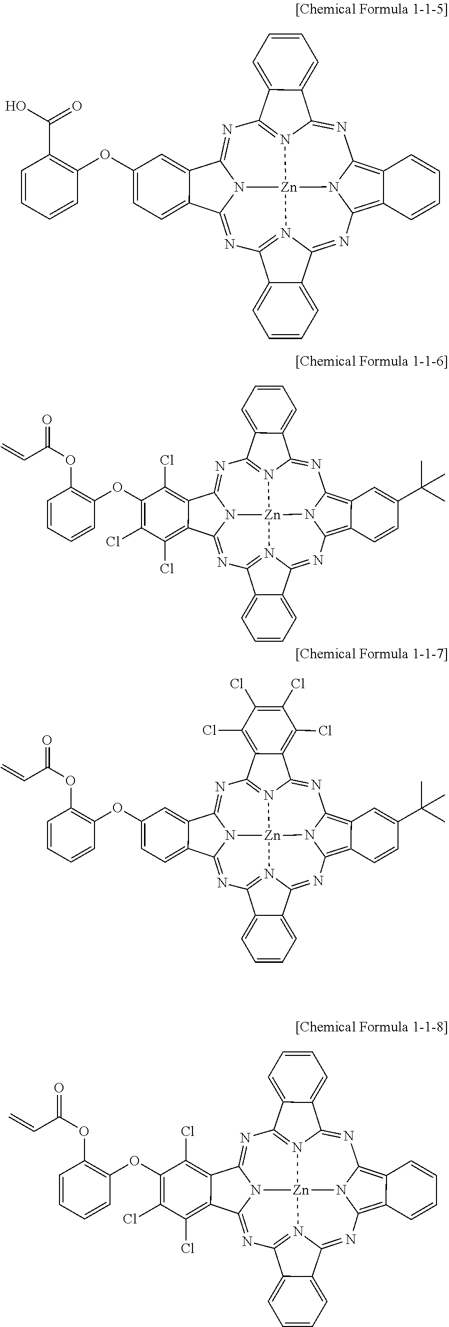

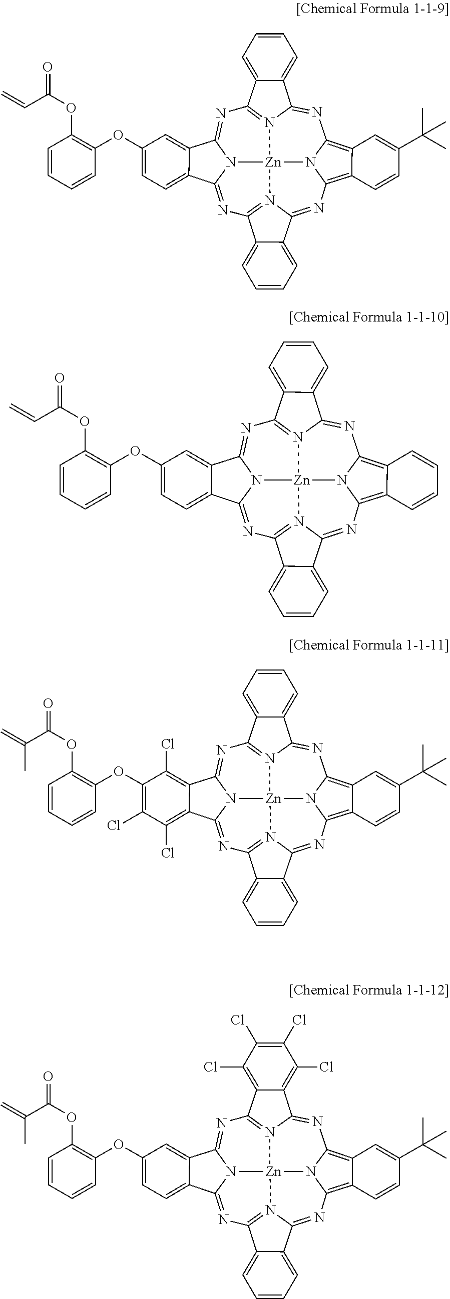

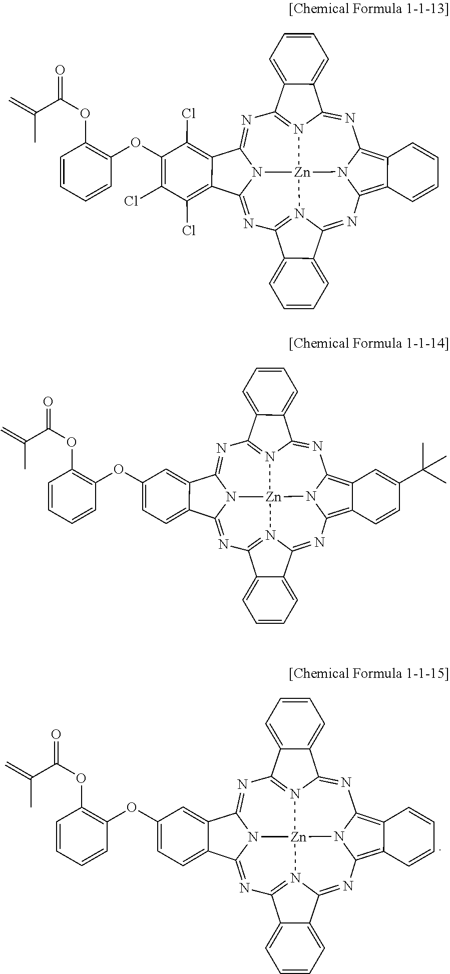

11. The photosensitive resin composition as claimed in claim 1, wherein the additive has a maximum absorption wavelength of about 580 nm to about 700 nm.

12. The photosensitive resin composition as claimed in claim 1, wherein the additive is included in an amount of about 0.01 wt % to about 5 wt % based on a total weight of the photosensitive resin composition.

13. The photosensitive resin composition as claimed in claim 1, wherein a weight ratio of the additive represented by Chemical Formula 1 and the pigment is about 1:1 to about 1:5.

14. The photosensitive resin composition as claimed in claim 1, wherein the colorant further includes a dispersion resin, a dispersion solvent, a dispersant, or a combination thereof.

15. The photosensitive resin composition as claimed in claim 1, wherein:
the colorant further includes a dispersion resin and a dispersion solvent, and
a content of the pigment is about 5 wt % to about 20 wt % based on a total weight of the pigment, the dispersion resin, and the dispersion solvent.

16. The photosensitive resin composition as claimed in claim 1, wherein the photosensitive resin composition includes:
about 30 wt % to about 70 wt % of the colorant;
about 1 wt % to about 30 wt % of the photopolymerizable compound;
about 0.1 wt % to about 10 wt % of the photopolymerization initiator;
about 1 wt % to about 20 wt % of the binder resin; and
the solvent, all wt % being based on a total weight of the photosensitive resin composition.

17. A photosensitive resin layer manufactured using the photosensitive resin composition according to claim 1.

18. The photosensitive resin layer as claimed in claim 17, wherein the photosensitive resin layer is a color negative photoresist.

19. A color filter comprising the photosensitive resin layer according to claim 17.

20. A CMOS image sensor comprising the color filter according to claim 19.
